(19) United States
(12) Patent Application Publication
(10) Pub. No.: US 2026/0152689 A1
(43) Pub. Date: Jun. 4, 2026

(54) ETCHANT COMPOSITION AND METHOD OF MANUFACTURING SEMICONDUCTOR DEVICE

(71) Applicant: Samsung Electronics Co., Ltd., Suwon-si (KR)

(72) Inventors: Minhyung Cho, Suwon-si (KR); Jinuk Lee, Seongnam-si (KR); Giho Ko, Suwon-si (KR); Daehan Kim, Seongnam-si (KR); Mihyun Park, Suwon-si (KR); Jungah Kim, Suwon-si (KR); Sangwon Bae, Suwon-si (KR); Junghun Lim, Seongnam-si (KR)

(73) Assignees: Samsung Electronics Co., Ltd., Suwon-si (KR); Soulbrain Co., Ltd., Seongnam-si (KR)

(21) Appl. No.: 19/317,612

(22) Filed: Sep. 3, 2025

(30) Foreign Application Priority Data
Nov. 29, 2024 (KR) 10-2024-0175822

(51) Int. Cl. C09K 13/06; H10D 30/00; H10D 30/01; H10D 30/43; H10D 62/10; H10D 62/13; H10D 64/01; H10D 64/23; H10D 84/83

(52) U.S. Cl. CPC C09K 13/06; H10D 30/014; H10D 30/0191; H10D 64/017; H10D 30/43; H10D 30/502; H10D 62/121; H10D 62/151; H10D 64/256; H10D 84/8312; H10D 84/832

(57) ABSTRACT

An etchant composition for etching a silicon nitride film, including an inorganic acid, a silicon-based additive, an ammonium-based compound, and a nitrogen-based additive, wherein the nitrogen-based additive is an amide-based compound including a substituted or unsubstituted aromatic ring having 5 to 15 carbon atoms, a substituted or unsubstituted non-aromatic ring having 5 to 15 carbon atoms, or a substituted or unsubstituted hydrocarbon chain having 1 to 12 carbon atoms, and a method of manufacturing a semiconductor device using the etchant composition are provided.

### CROSS-REFERENCE TO RELATED APPLICATION

This application is based on and claims priority under 35 U.S.C. § 119 to Korean Patent Application No. 10-2024-0175822, filed on Nov. 29, 2024, in the Korean Intellectual Property Office, the disclosure of which is incorporated by reference herein in its entirety.

### FIELD

The present inventive concept relates to an etchant composition and a method of manufacturing a semiconductor device using the same, and more specifically, to an etchant composition for selective etching of a silicon nitride film and a method of manufacturing a semiconductor device using the same.

### BACKGROUND

As electronic products become smaller, more multifunctional, and have higher performance, high-capacity and high-integration circuits are required. Accordingly, it is necessary to efficiently design wiring structures to achieve high integration while securing the functions and operating speeds required for integrated circuit devices.

### SUMMARY

The present inventive concept provides an etchant composition capable of realizing a high etching selectivity of a silicon nitride film over a silicon film including doped silicon or silicon germanium.

The present inventive concept provides a method of manufacturing a semiconductor device, which may provide a semiconductor device with improved performance and reliability due to a high etching selectivity of a silicon nitride film with respect to a doped silicon film and a silicon germanium film during the manufacturing process of the semiconductor device.

According to an aspect of the present inventive concept, there is provided an etchant composition for etching a silicon nitride film including an inorganic acid, a silicon-based additive, an ammonium-based compound, and a nitrogen-based additive, wherein the nitrogen-based additive is an amide-based compound including a substituted or unsubstituted aromatic ring having 5 to 15 carbon atoms, a substituted or unsubstituted non-aromatic ring having 5 to 15 carbon atoms, or a substituted or unsubstituted hydrocarbon chain having 1 to 12 carbon atoms.

According to an aspect of the present inventive concept, there is provided a method of manufacturing a semiconductor device, the method including forming a stacked structure in which a plurality of sacrificial semiconductor layers and a plurality of nanosheet semiconductor layers are alternately stacked one by one on a substrate, forming a plurality of dummy gate structures on the stacked structure, sequentially forming a plurality of insulating spacers and a spacer sacrificial film covering both sidewalls of each of the plurality of dummy gate structures, forming a first recess penetrating the plurality of sacrificial semiconductor layers and the plurality of nanosheet semiconductor layers by using the plurality of dummy gate structures, forming a source/drain region inside the first recess, and removing the spacer sacrificial film using an etchant composition for etching a silicon nitride film, wherein the etchant composition for etching a silicon nitride film includes an inorganic acid, a silicon-based additive, an ammonium-based compound, and a nitrogen-based additive, and wherein the nitrogen-based additive comprises an amide-based compound including a substituted or unsubstituted aromatic ring having 5 to 15 carbon atoms, or a substituted or unsubstituted non-aromatic ring having 5 to 15 carbon atoms, or a substituted or unsubstituted hydrocarbon chain having 1 to 12 carbon atoms.

According to an aspect of the present inventive concept, there is provided an etchant composition for etching a silicon nitride film, including an inorganic acid included in a content of about 7 wt % to about 85 wt % based on the total amount of the etchant composition, a silicon-based additive included in a content of about 0.1 wt % to about 10 wt % based on the total amount of the etchant composition, an ammonium-based compound included in a content of about 0.1 wt % to about 10 wt % based on the total amount of the etchant composition, a nitrogen-based additive included in a content of about 0.1 wt % to about 10 wt % based on the total amount of the etchant composition, and a solvent, wherein the nitrogen-based additive comprises an amide-based compound including a substituted or unsubstituted aromatic ring having 5 to 15 carbon atoms, a substituted or unsubstituted non-aromatic ring having 5 to 15 carbon atoms, or a substituted or unsubstituted hydrocarbon chain having 1 to 12 carbon atoms.

### BRIEF DESCRIPTION OF THE DRAWINGS

Embodiments will be more clearly understood from the following detailed description taken in conjunction with the accompanying drawings in which:

FIG. 1 is a flowchart for explaining a method of manufacturing a semiconductor device, according to embodiments; and

FIGS. 2A to 2K are cross-sectional views for explaining each operation of a method of manufacturing a semiconductor device, according to embodiments.

### DETAILED DESCRIPTION OF THE EMBODIMENTS

Hereinafter, embodiments of the technical idea of the inventive concept will be described in detail with reference to the accompanied drawings. The same reference numerals are used for the same components in the drawings, and overlapping descriptions thereof are omitted.

An etchant composition according to embodiments may include an inorganic acid, an ammonium-based compound, a nitrogen-based additive, a silicon-based additive, and a solvent.

In example embodiments, the inorganic acid may be sulfuric acid, nitric acid, phosphoric acid, silicic acid, hydrofluoric acid, boric acid, hydrochloric acid, perchloric acid, or any combination thereof.

In example embodiments, the ammonium-based compound may be ammonium chloride, ammonium phosphate, ammonium acetate, ammonium sulfate, ammonium formate, a metal amine complex salt, or any combination thereof. In an etching process using an etchant composition according to example embodiments, the ammonium-based compound may prevent abnormal growth of an oxide film by a silicon-based compound included in the etchant composition. In embodiments, the ammonium-based compound may function as an abnormal growth inhibitor that suppresses abnormal growth of an oxide film.

In example embodiments, the nitrogen-based additive may be composed of an amide-based compound including a substituted or unsubstituted aromatic ring having 5 to 15 carbon atoms, a substituted or unsubstituted non-aromatic ring having 5 to 15 carbon atoms, or a substituted or unsubstituted hydrocarbon chain having 1 to 12 carbon atoms.

For example, the amide-based compound may include N-alkyl formamides such as N-methylformamide, N-ethylformamide, N-propylformamide, N-butylformamide, N-pentylformamide, N-hexylformamide, N-heptylformamide, N-octylformamide, N-nonylformamide, N,N-dimethylformamide, N,N-diethylformamide; N-alkyl acetamides such as

N-methylacetamide and N,N-dimethylacetamide; propanamide, butanamide, pentanamide, hexanamide, heptanamide, octanamide, nonanamide, nicotinamide, urea, N-allylthiourea, 2-pyrrolidone, or any combination thereof. In embodiments, the nitrogen-based additive may function as an etching suppressor that suppresses the etching of a silicon film including SiGe or Si doped with impurities.

In example embodiments, the silicon-based additive may include a silicon-based compound represented by the following Chemical Formula 1.

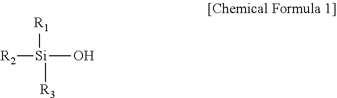

In Chemical Formula 1, R₁, R₂, and R₃ are each independently selected from the group consisting of a substituted or unsubstituted amino alkyl group having 1 to 20 carbon atoms, a substituted or unsubstituted alkoxy group having 1 to 20 carbon atoms, a substituted or unsubstituted acetyloxy group having 1 to 20 carbon atoms, and a substituted or unsubstituted haloalkylacetyloxy group having 1 to 20 carbon atoms, wherein at least one of R₁, R₂, and R₃ is a substituted or unsubstituted amino alkyl group having 1 to 20 carbon atoms.

In example embodiments, the silicon-based additive may include, for example, 3-Aminopropylsilanetriol (APST), methylsilanetriol, chloromethyl (trihydroxy) silane, Methyltriethoxysilane, Methyltrimethoxysilane, tri-(ethyl, methylamino-silane) methyl siloxane, tri-(di-ethylamino-silane) amino propyl siloxane, or any combination thereof. In an etching process using an etchant composition according to example embodiments, a silicon-based compound precipitated from the silicon-based additive may bind to a surface of an oxide film, which is not an etching target film of the etching process, thereby preventing the oxide film from being etched. In embodiments, the silicon-based additive may function as an oxide film etching inhibitor that suppresses etching of the oxide film.

In the etchant composition according to example embodiments, the inorganic acid may be included in an amount of about 7 wt % to about 85 wt %, or any range therein, based on the total amount of the etchant composition, for example, about 7 wt % to about 45 wt %, about 45 wt % to about 85 wt %, or about 20 wt % to about 50 wt %. The silicon-based additive may be included in an amount of about 0.1 wt % to about 10 wt %, or any range therein, based on the total amount of the etchant composition, for example, about 0.1 wt % to about 5 wt %, about 5 wt % to about 10 wt %, about 2 wt % to about 8 wt %, or about 3 wt % to about 7 wt %. The nitrogen-based additive may be included in an amount of about 0.1 wt % to about 10 wt %, or any range therein, based on the total amount of the etchant composition for example, about 0.1 wt % to about 5 wt %, about 5 wt % to about 10 wt %, about 2 wt % to about 7 wt %, about 0.5 wt % to about 3 wt %, or about 1 wt % to about 2 wt %. The ammonium-based compound may be included in an amount of about 0.1 wt % to about 10 wt %, or any range therein, based on the total amount of the etchant composition for example, about 0.1 wt % to about 5 wt %, about 5 wt % to about 10 wt %, about 2 wt % to about 7 wt %, about 0.1 wt % to about 4 wt % or about 0.5 wt % to about 3 wt %. The content of the solvent may be included as a residual amount excluding the contents of the inorganic acid, the silicon-based additive, the nitrogen-based additive, and the ammonium compound. If the content of each of the inorganic acid, the silicon-based additive, the nitrogen-based additive, and the ammonium compound included in the etchant composition is outside the range described above, the etching prevention of a silicon film including SiGe or Si doped with an impurity may not be performed well, the etching prevention of an oxide film may not be performed well, or the etching of a nitride film may not be performed well.

The solvent may be an organic solvent. The organic solvent may be selected from, for example, acetic acid, methyl acetate, ethyl acetate, propyl acetate, isopropyl acetate, ethanol, methanol, butanol, propanol, ethylene carbonate, diethyl carbonate, dimethyl carbonate, ethyl methyl carbonate, propylene carbonate, methylpropyl carbonate, and any combination thereof.

In example embodiments, the etchant composition according to embodiments may not include water. In other example embodiments, the etchant composition according to embodiments may further include water in an amount greater than about 0 wt % and less than about 1 wt %, or any range therein, for example, less than 0.9 wt %, less than 0.8 wt %, less than 0.7 wt %, less than 0.6 wt %, less than 0.5 wt %, based on the total amount of the etchant composition.

In example embodiments, the etching selectivity of the silicon nitride film to the oxide film of the etchant composition according to example embodiments may be about 10 or more.

The etchant composition according to example embodiments may include a silicon-based additive that prevents etching of the silicon film including the oxide film and SiGe or Si doped with an impurity, and a nitrogen-based additive that promotes further bonding of the silicon-based compound precipitated from the silicon-based additive to the silicon film. Therefore, when performing an etching process using the etchant composition according to example embodiments, a high etching selectivity of the silicon nitride film to the silicon film may be realized compared to a case when an etchant composition that does not include the nitrogen-based additive is used. Accordingly, a semiconductor device manufactured by performing an etching process using the etchant composition according to example embodiments may have improved performance and reliability.

Hereinafter, the above-described effects of the etchant composition according to example embodiments will be described in more detail with reference to comparative examples and example embodiments.

TABLE 1

| | | | Ammonium-based | | Nitrogen-based | |
|---|---|---|---|---|---|---|
| | Silicon-based oxide film etching inhibitor | | abnormal growth inhibitor | | additive (kind/content) | |
| | | Content | | Content | | Content |
| | kind | (wt %) | kind | (wt %) | kind | (wt %) |
| Embodiment 1 | APST | 3 | Ammonium | 1 | L-Histidinamide | 1 |
| | | | phosphate | | 2% | |
| Embodiment 2 | APST | 5 | Diammonium | 3 | Methylacetamide | 2 |
| | | | phosphate | | | |
| Embodiment 3 | APST | 7 | Ammonium | 2 | 2-Pyrrolidone | 2 |
| | | | acetate | | | |
| Embodiment 4 | 3-Aminopropyldiethoxymethylsilane | 3 | Ammonium | 0.5 | Urea | 2 |
| | | | nitride | | | |
| Embodiment 5 | (HYDROXYETHYL)-N- | 3 | Ammonium | 1 | N-acetylcysteine | 1 |
| | METHYLAMONIPROPYL | | citrate | | amide | |
| | TRIMETHOXYSILANE | | | | | |
| Embodiment 6 | UREIDOPROPYLTRIETHOXYSILANE | 3 | Ammonium | 1 | Benzamide | 2 |
| | | | formate | | | |
| Comparative example 1 | APST | 3 | Not include | — | Not include | — |
| Comparative example 2 | APST | 5 | Diammonium | | Not include | — |
| | | | phosphate | | | |
| Comparative example 3 | APST | 7 | Not include | — | 2-Pyrrolidone | 2 |
| Comparative example 4 | Not included | — | Ammonium | 1 | L-Histidineamide | 1 |
| | | | phosphate | | 2% | |
| Comparative example 5 | methyltriethoxysilane | 3 | Ammonium | 1 | L-Histidineamide | 1 |
| | | | phosphate | | 2% | |
| Comparative example 6 | Ethylsilanetriol triactate 3% | 5 | Diammonium | 3 | Methylacetamide | 2 |
| | | | phosphate | | | |

Table 1 shows the etchant compositions according to example embodiments and etchant compositions according to comparative examples, respectively.

In the examples and comparative examples of Table 1, each of the etchant composition includes an inorganic acid as a remainder excluding the contents of the silicon-based additive, the nitrogen-based additive, and the ammonium compound, and the inorganic acid may be formed of an 85 wt % phosphoric acid aqueous solution.

TABLE 2

| | SiN | Oxide film | SiGe | Doped Si |
|---|---|---|---|---|
| | etching rate | etching rate | etching rate | etching rate |
| Embodiment 1 | 46.5 | 0.28 | 0.45 | 0.05 |
| Embodiment 2 | 46.5 | 0.2 | 0.44 | 0.04 |
| Embodiment 3 | 46.8 | 0.16 | 0.4 | 0.06 |
| Embodiment 4 | 46.1 | 0.25 | 0.45 | 0.05 |
| Embodiment 5 | 47.2 | 0.26 | 0.44 | 0.04 |
| Embodiment 6 | 45.9 | 0.21 | 0.42 | 0.05 |
| Comparative | 46.8 | 0.3 | 2.45 | 2.76 |
| Example 1 | | | | |
| Comparative | 46.3 | 0.29 | 0.55 | 2.7 |
| Example 2 | | | | |
| Comparative | 46.1 | 0.22 | 0.85 | 1.22 |
| Example 3 | | | | |
| Comparative | 45.9 | 3.02 | 4.2 | 1.05 |
| Example 4 | | | | |
| Comparative | 46.3 | 1.01 | 0.93 | 0.13 |
| Example 5 | | | | |
| Comparative | 46.7 | 0.69 | 1.25 | 0.14 |
| Example 6 | | | | |

Table 2 shows etching rates when etching a silicon nitride film, an oxide film, a SiGe film, and a Si film doped with an impurity by using the etchant compositions according to the example embodiments shown in Table 1 and the etchant compositions according to the comparative examples, respectively.

When comparing Embodiment 2 with Comparative Example 2, it may be confirmed that the etching rate of the silicon nitride film in the etching process using the etchant composition in Example 2 is almost similar to the etching rate of the silicon nitride film in the etching process using the etchant composition in Comparative Example 2. In addition, it may be confirmed that the etching rate of the SiGe film and the etching rate of the Si film doped with an impurity in the etching process using the etchant composition in Example 2 are significantly lower than the etching rate of the SiGe film and the etching rate of the Si film doped with an impurity in the etching process using the etchant composition in Comparative Example 2. That is, when comparing Embodiment 2 with Comparative Example 2, it may be confirmed that the etching process using the etchant composition in Embodiment 2 maintains a similar etching rate of the silicon nitride film as the etching process using the etchant composition in Comparative Example 2, while having a significantly lower etching rate of the SiGe film and the etching rate of the Si film doped with an impurity. It is presumed, without being bound by theory, that this is because the nitrogen-based additive included in the etchant composition of Embodiment 2 strengthens the bonding between the silicon-based compounds precipitated from the silicon-based additive, thereby preventing the etching of the SiGe film or the Si film doped with an impurity.

When comparing Embodiment 1 with Comparative Example 4, it may be confirmed that the etching rate of the silicon nitride film in the etching process using the etchant composition in Embodiment 1 is similar to the etching rate of the silicon nitride film in the etching process using the etchant composition in Comparative Example 4. In addition, it may be confirmed that the etching rate of the oxide film in the etching process using the etchant composition in Embodiment 1 is significantly lower than the etching rate of the oxide film in the etching process using the etchant composition in Comparative Example 4. In addition, it may be confirmed that the etching rate of the SiGe film and the etching rate of the Si film doped with an impurity in the etching process using the etchant composition in Embodiment I are significantly lower than the etching rate of the SiGe film and the etching rate of the Si film doped with an impurity in the etching process using the etchant composition in Comparative Example 4. That is, when comparing Embodiment 1 with Comparative Example 4, it may be confirmed that the etching process using the etchant composition in Embodiment 1 maintains a silicon nitride film etching rate similar to that of the etching process using the etchant composition in Comparative Example 4, while having a generally lower etching rate of the oxide film and a significantly lower etching rate of the SiGe film and the etching rate of the Si film doped with an impurity. It is presumed, without being bound by theory, that because the silicon-based additive included in the etchant composition of Embodiment 1 prevents the etching of the oxide film, and the etching of the SiGe film or the Si film doped with an impurity is prevented due to the bonding between the silicon-based compounds precipitated from the silicon-based additive.

In addition, when comparing Embodiments 1 and 2 with Comparative Examples 5 and 6, it may be confirmed that the etching rate of the silicon nitride film in the etching process using the etchant compositions of Embodiments 1 and 2 is similar to the etching rate of the silicon nitride film in the etching process using the etchant compositions of Comparative Examples 5 and 6. In addition, it may be confirmed that the etching rate of the oxide film in the etching process using the etchant composition of Embodiments 1 and 2 is significantly lower than the etching rate of the oxide film in the etching process using the etchant compositions of Comparative Examples 5 and 6. In addition, it may be confirmed that the etching rate of the SiGe film and the etching rate of the Si film doped with an impurity in the etching process using the etchant compositions of Embodiments 1 and 2 are significantly lower than the etching rate of the SiGe film and the etching rate of the Si film doped with an impurity in the etching process using the etchant compositions of Comparative Examples 5 and 6. That is, when comparing Embodiments 1 and 2 with Comparative Examples 5 and 6, it may be confirmed that the etching process using the etchant compositions of Embodiments 1 and 2 maintains a silicon nitride film etching rate similar to that of the etching process using the etchant compositions of Comparative Examples 5 and 6, while having a generally lower etching rate of the oxide film and a significantly lower etching rate of the SiGe film and the etching rate of the S film doped with an impurity. It is presumed, without being bound by theory, that this is because the silicon-based additive included in the etchant compositions of Embodiments 1 and 2 has improved oxide film etching prevention performance compared to the silicon-based additive included in the etchant compositions of Comparative Examples 5 and 6, and the etching of the SiGe film or the Si film doped with an impurity is prevented due to bonding between silicon-based compounds precipitated from the silicon-based additive.

Comparing Embodiment 3 to Comparative Example 3, it may be confirmed that the etching rate of the silicon nitride film in the etching process using the etchant composition in Embodiment 3 is similar to the etching rate of the silicon nitride film in the etching process using the etchant composition in Comparative Example 3. In addition, it may be confirmed that the etching rate of the oxide film in the etching process using the etchant composition in Embodiment 3 is generally lower than the etching rate of the oxide film in the etching process using the etchant composition in Comparative Example 3. In addition, it may be confirmed that the etching rate of the SiGe film and the etching rate of the Si film doped with an impurity in the etching process using the etchant composition in Embodiment 3 are significantly lower than the etching rate of the SiGe film and the etching rate of the Si film doped with an impurity in the etching process using the etchant composition in Comparative Example 3. That is, when comparing Embodiment 3 with Comparative Example 3, it may be confirmed that the etching process using the etchant composition in Embodiment 3 maintains a silicon nitride film etching rate similar to that of the etching process using the etchant composition in Comparative Example 3, while having a generally lower etching rate of the oxide film and a significantly lower etching rate of the SiGe film and the etching rate of the Si film doped with an impurity.

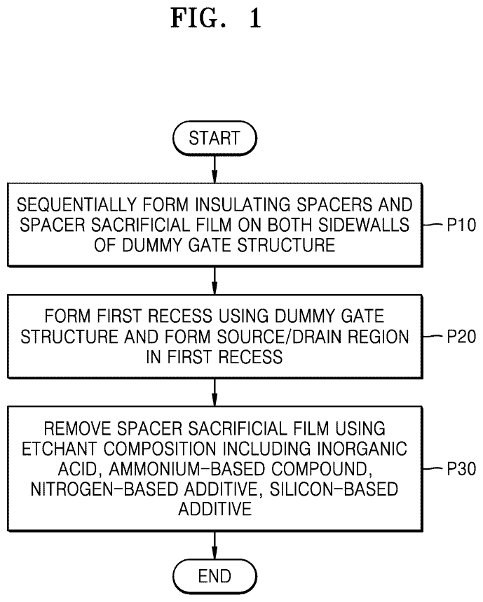

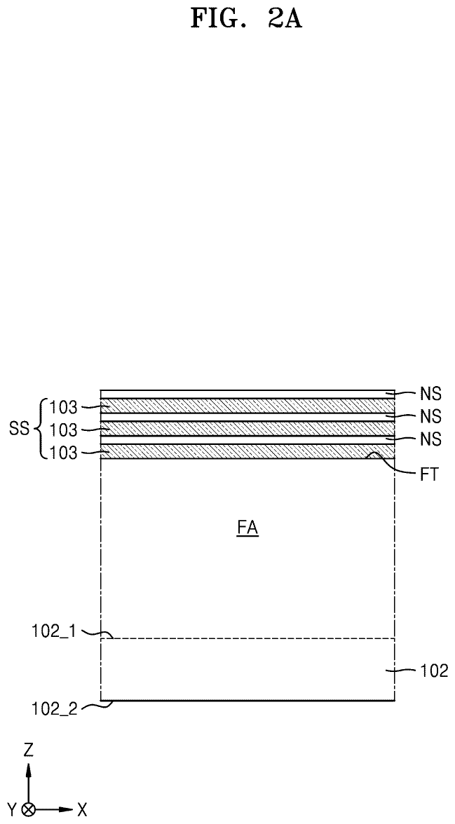

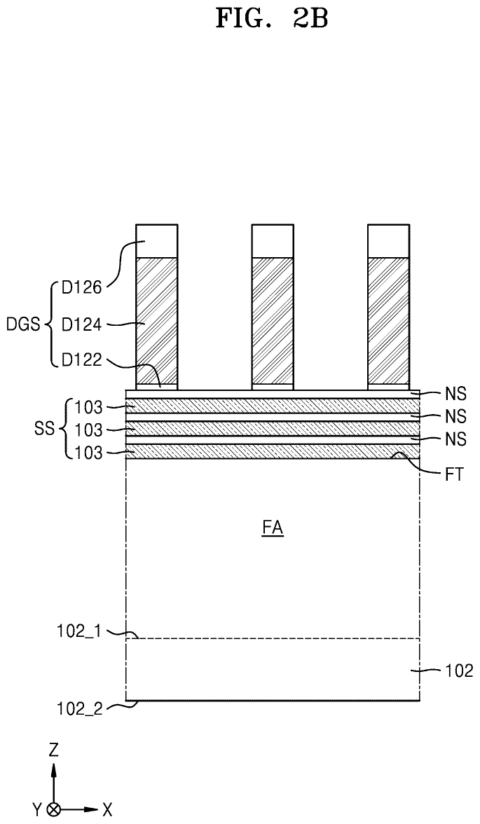

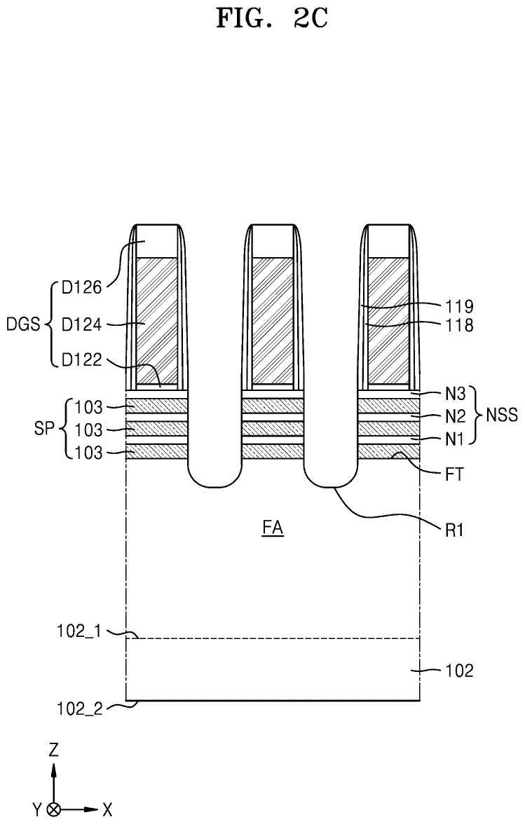

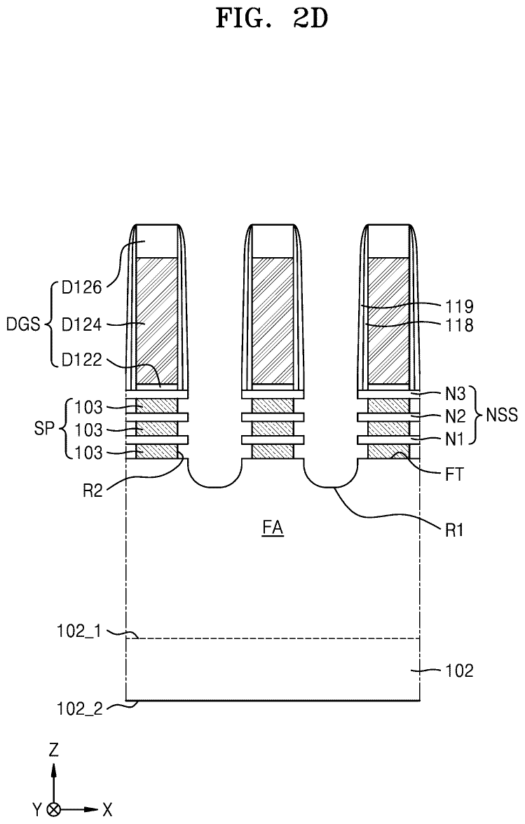

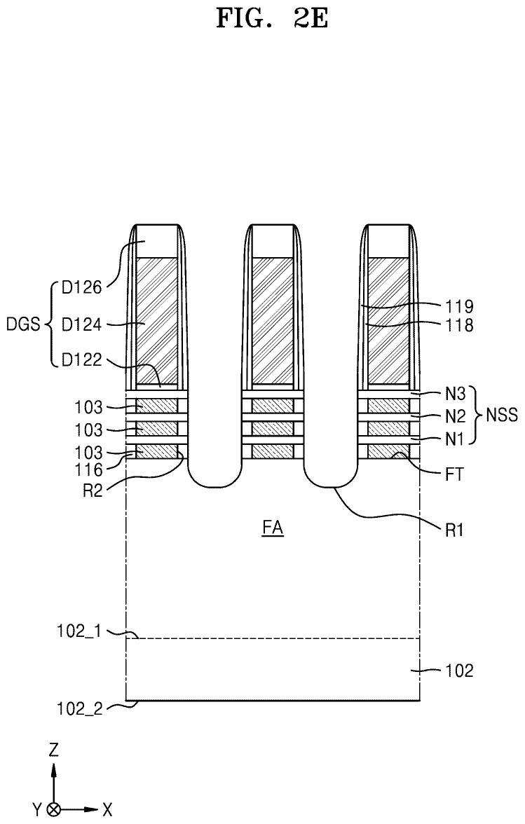

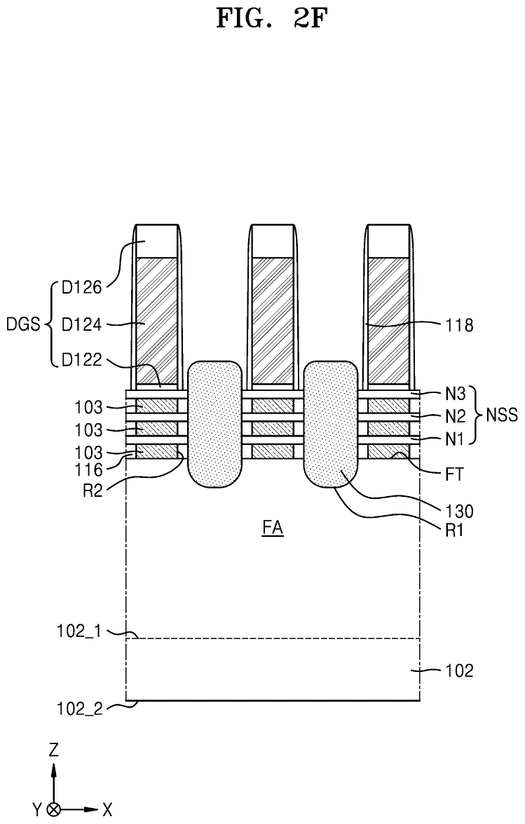

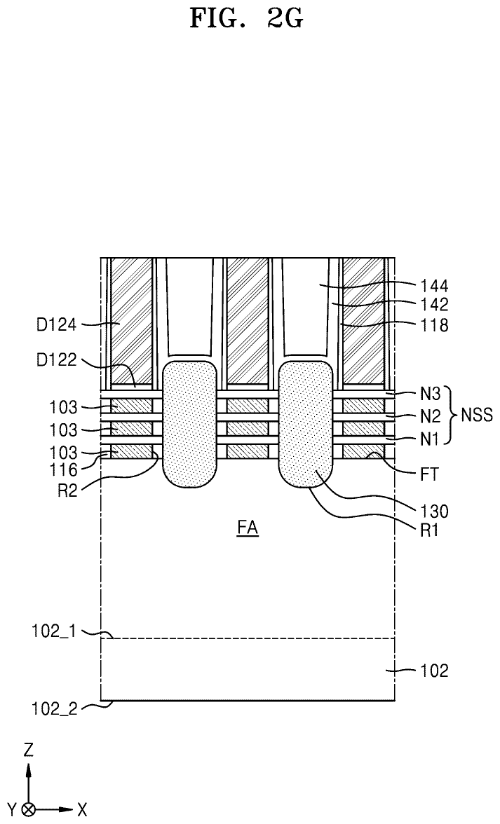

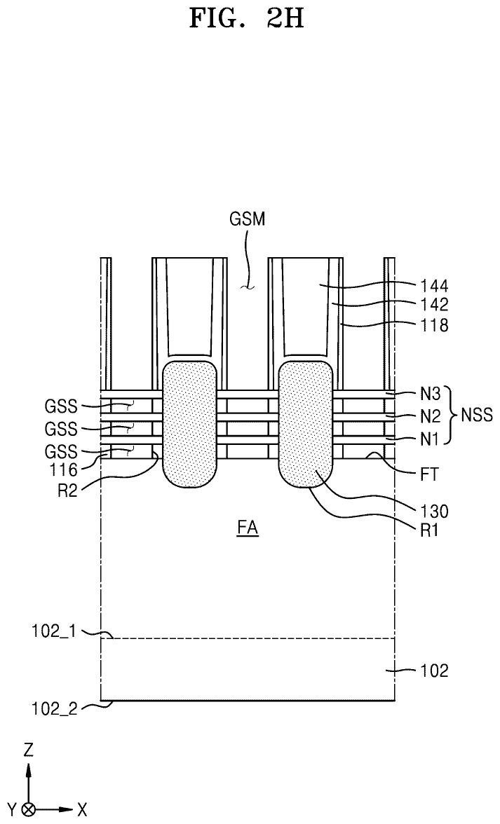

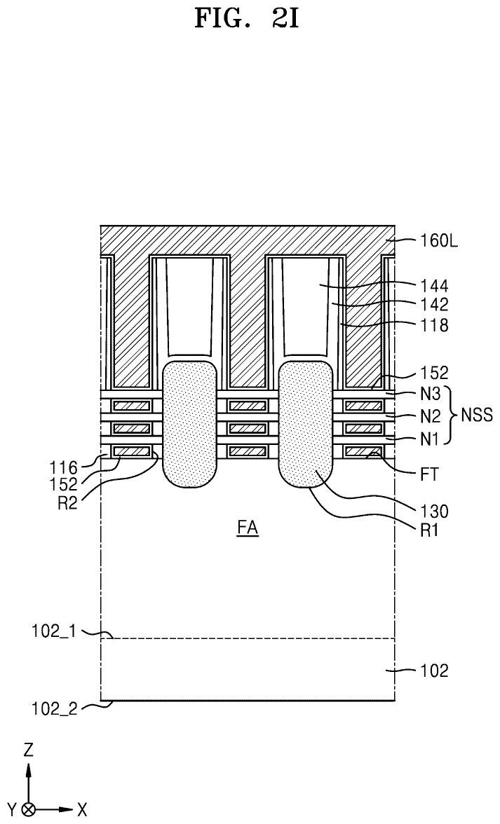

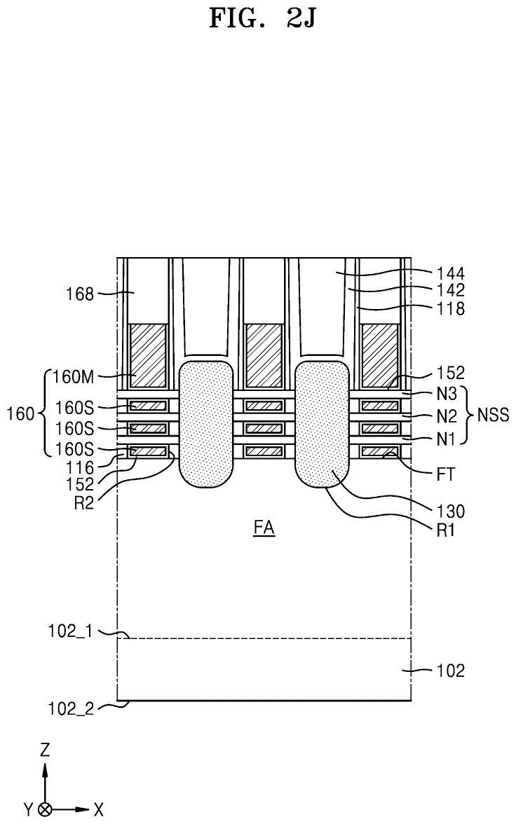

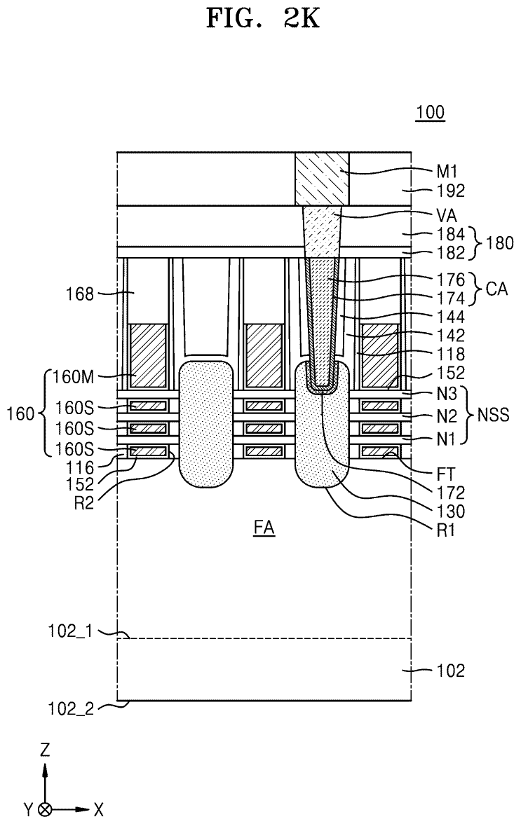

FIG. 1 is a flowchart for explaining a method of manufacturing a semiconductor device, according to example embodiments. FIGS. 2A to 2K are cross-sectional views for explaining each operation of a method of manufacturing a semiconductor device, according to example embodiments.

Referring to FIG. 2A, a stacked structure SS in which a plurality of sacrificial semiconductor layers 103 and a plurality of nanosheet semiconductor layers NS are alternately stacked one layer at a time on a substrate 102 may be formed. The plurality of sacrificial semiconductor layers 103 and the plurality of nanosheet semiconductor layers NS may include semiconductor materials having different etching selectivities.

The substrate 102 may include a semiconductor element s such as Si or Ge, or a compound semiconductor such as SiGe, SiC, GaAs, InAs, InGaAs, or InP.

The plurality of sacrificial semiconductor layers 103 and the plurality of nanosheet semiconductor layers NS constituting the stacked structure SS may each be formed by an epitaxial growth process. In example embodiments, the plurality of nanosheet semiconductor layers NS may include a single crystal Si film, and the plurality of sacrificial semiconductor layers 103 may include a SiGe film.

Next, the sacrificial semiconductor layer 103, the plurality of nanosheet semiconductor layers NS, and a portion of the substrate 102 may be etched to form a plurality of fin-shaped active regions FA extending in a first horizontal direction (X direction) on the substrate 102. By this, a first surface 102_1 of the substrate 102 is formed, and a plurality of fin-type active regions FA may be arranged on the first surface 102_1 of the substrate 102. The plurality of sacrificial semiconductor layers 103 and the plurality of nanosheet semiconductor layers NS of the stacked structure SS may remain on a fin upper surface FT of each of the plurality of fin-type active regions FA.

Referring to FIG. 2B, a plurality of dummy gate structures DGS may be formed on the stacked structure SS.

The plurality of dummy gate structures DGS may be formed to extend in a second horizontal direction (Y direction). The plurality of dummy gate structures DGS may each have a structure in which an oxide film D122, a dummy gate layer D124, and a capping layer D126 are sequentially stacked. In some embodiments, the dummy gate layer D124 may include polysilicon, and the capping layer D126 may include a silicon nitride film.

Referring to FIGS. 1 and 2C, after forming a plurality of insulating spacers 118 and a spacer sacrificial film 119 covering both side surfaces of each of the plurality of dummy gate structures DGS (P10), a portion of the plurality of sacrificial semiconductor layers 103 and a portion of the plurality of nanosheet semiconductor layers NS may be etched using the plurality of dummy gate structures DGS, the plurality of insulating spacers 118, and the spacer sacrificial film 119 as etching masks (P20). As a result, the plurality of nanosheet semiconductor layers NS may be divided into a plurality of nanosheet stacks NSS each including a first nanosheet N1, a second nanosheet N2, and a third nanosheet N3.

By the etching process, a stacked pattern SP including a plurality of sacrificial semiconductor layers 103 and a plurality of nanosheets N1, N2, and N3 may be formed.

By the etching process, a plurality of first recesses R1 exposing sidewalls of the stacked pattern SP may be formed. The plurality of first recesses R1 may penetrate the plurality of sacrificial semiconductor layers 103 and the plurality of nanosheet semiconductor layers NS in the vertical direction (Z direction). In order to form the plurality of first recesses R1, etching may be performed using dry etching, wet etching, or a combination thereof.

In example embodiments, the insulating spacer 118 may include silicon nitride, silicon oxide, SiCN, SiBN, SION, SiOCN, SiBCN, SiOC, or any combination thereof. The terms “SiCN”, “SiBN”, “SiON”, “SiOCN”, “SiBCN”, and “SiOC” used in this specification denote materials composed of elements included in each term and are not chemical formulas representing stoichiometric relationships. For example, the insulating spacer 118 may include silicon oxide.

In example embodiments, the spacer sacrificial film 119 may include silicon nitride.

Referring to FIG. 1 and FIG. 2D, a portion of each of the plurality of sacrificial semiconductor layers 103 among the stacked patterns SP exposed by each of the plurality of first recesses R1 may be removed to form a plurality of second recesses R2.

In order to form the plurality of second recesses R2, an etchant composition may be applied to the stacked patterns SP through the plurality of first recesses R1. By applying the etchant composition to the stacked pattern SP, a portion of each of the plurality of sacrificial semiconductor layers 103 may be selectively removed from among the plurality of nanosheets N1, N2, and N3 and the plurality of sacrificial semiconductor layers 103.

Referring to FIG. 2E, a plurality of inner insulating spacers 116 may be formed within the plurality of second recesses R2. The plurality of inner insulating spacers 116 may include silicon nitride.

Referring to FIG. 1 and FIG. 2F, a plurality of source/drain regions 130 may be formed within each of the plurality of first recesses R1 (P20). In example embodiments, in order to form the plurality of source/drain regions 130, a semiconductor material may be epitaxially grown from a surface of the fin-shaped active region FA exposed from a bottom surface of each of the plurality of first recesses R1, sidewalls of each of the first nanosheets N1, the second nanosheets N2, and the third nanosheets N3 included in the nanosheet stack NSS, and sidewalls of each of the plurality of sacrificial semiconductor layers 103. The plurality of source/drain regions 130 may include SiGe or Si doped with an impurity. The impurity may be, for example, a p-type impurity or an n-type impurity.

Next, using the etchant composition according to example embodiments, the spacer sacrificial film 119 (see FIG. 2E) may be removed from the sidewall of the insulating spacer 118 (P30). The specific configuration of the etchant composition is the same as the etchant composition described above according to the example embodiments. The spacer sacrificial film 119 (see FIG. 2E) is removed, and thus, an outer sidewall of the insulating spacer 118 may be exposed.

When the spacer sacrificial film 119 (see FIG. 2E) including silicon nitride is removed using the etchant composition according to example embodiments, the etchant composition may implement a high etching selectivity of the silicon nitride film with respect to silicon oxide, Si doped with an impurity, and SiGe, and thus, the source/drain region 130 may be prevented from being etched during a process of removing the spacer sacrificial film 119. Accordingly, the performance and reliability of the semiconductor device 100 (see FIG. 2K) that will be manufactured by performing the process described below may be improved.

Referring to FIG. 2G, an insulating liner 142 covering the resultant product of FIG. 2F in which the plurality of source/drain regions 130 are formed is formed, an inter-gate insulating film 144 is formed on the insulating liner 142, and then, an upper surface of the capping layer D126 may be exposed by planarizing the insulating liner 142 and the inter-gate insulating film 144.

Next, the capping layer D126 is removed to expose an upper surface of the dummy gate layer D124, and the insulating liner 142 and the inter-gate insulating film 144 may be partially removed so that an upper surface of the inter-gate insulating film 144 and an upper surface of the dummy gate layer D124 are approximately at the same level.

Referring to FIG. 2H, the dummy gate layer D124 and the oxide film D122 thereunder are removed to provide a main gate space GSM, and a plurality of nanosheet stacks NSS may be exposed through the main gate space GSM.

Next, the plurality of sacrificial semiconductor layers 103 remaining on the fin-type active region FA may be removed through the main gate space GSM to provide a sub-gate space GSS between each of the first nanosheet N1, the second nanosheet N2, and the third nanosheet N3 and between the first nanosheet N1 and an upper surface of the fin.

In example embodiments, in order to selectively remove the plurality of sacrificial semiconductor layers 103, a difference in etching selectivity between the first nanosheet N1, the second nanosheet N2, and the third nanosheet N3 and the plurality of sacrificial semiconductor layers 103 may be utilized.

Referring to FIG. 2I, a gate dielectric film 152 may be formed within the main gate space GSM and the sub-gate space GSS. The gate dielectric film 152 covering an exposed surface of the third nanosheet N3 may be formed in the main gate space GSM. The gate dielectric film 152 covering multiple nanosheets N1, N2, and N3 may be formed in the sub-gate space GSS. An atomic layer deposition (ALD) process may be used to form the gate dielectric film 152.

Next, a gate-forming conductive layer 160L may be formed on the gate dielectric film 152 to cover the upper surface of the inter-gate insulating film 144 while filling the main gate space GSM and the sub-gate space GSS. The gate-forming conductive layer 160L may include a metal, a metal nitride, a metal carbide, or any combination thereof. An ALD process or a chemical vapor deposition (CVD) process may be used to form the gate-forming conductive layer 160L.

Referring to FIG. 2J, the gate-forming conductive layer 160L may be partially removed from an upper surface thereof so that the upper surface of the inter-gate insulating film 144 is exposed and a portion of an upper side of the main gate space GSM (see FIG. 2G) is emptied again. As a result, a plurality of gate lines 160 may be formed from the gate forming conductive layer 160L.

At this time, the gate dielectric film 152 and the outer insulating spacer 118 in the main gate space GSM may be partially consumed from their respective upper sides, and thus, heights of the gate dielectric film 152 and the outer insulating spacer 118 may be lowered, respectively. Thereafter, a capping insulating pattern 168 that fills the main gate space GSM may be formed on the gate line 160.

Referring to FIG. 2K, an active contact CA penetrating the insulating liner 142 and the inter-gate insulating film 144 may be formed. The active contact CA may penetrate the inter-gate insulating film 144 and the insulating liner 142 in the vertical direction (Z direction) and may contact a first metal silicide film 172. The active contact CA may be configured to be electrically connected to the source/drain region 130 through the first metal silicide film 172.

The active contact CA may include a conductive barrier pattern 174 and a contact plug 176 sequentially stacked on the source/drain region 130. The conductive barrier pattern 174 may surround a bottom surface and sidewall of the contact plug 176 and may contact the bottom surface and sidewall of the contact plug 176. The active contact CA may extend in the vertical direction (Z direction) by penetrating the inter-gate insulating film 144 and the insulating liner 142. The conductive barrier pattern 174 may be disposed between the first metal silicide film 172 and the contact plug 176. The conductive barrier pattern 174 may have a surface contacting the first metal silicide film 172 and a surface contacting the contact plug 176. In example embodiments, the conductive barrier pattern 174 may include a metal or a metal nitride. For example, the conductive barrier pattern 174 may include, but is not limited to, Ti, Ta, W, TiN, TaN, WN, WCN, TiSiN, TaSiN, WSiN, or any combination thereof. The contact plug 176 may include, but is not limited to, molybdenum (Mo), copper (Cu), tungsten (W), cobalt (Co), ruthenium (Ru), manganese (Mn), titanium (Ti), tantalum (Ta), aluminum (Al), any combination thereof, or an alloy thereof.

Next, an upper insulating structure 180 covering an upper surface of each of the active contact CA, the capping insulating pattern 168, and the inter-gate insulating film 144 may be formed. The upper insulating structure 180 may include an etching stop film 182 and an interlayer insulating film 184 sequentially stacked on each of the active contact CA, the plurality of capping insulating patterns 168, and the inter-gate insulating film 144. The etching stop film 182 may include silicon carbide (SiC), silicon nitride (SiN), nitrogen-doped silicon carbide (SiC: N), SiOC, AlN, AlON, AlO, AlOC, or a combination thereof. The interlayer insulating film 184 may include an oxide film, a nitride film, an ultra-low k (ULK) film having an ultra-low dielectric constant K of about 2.2 to about 2.4, or any combination thereof. For example, the interlayer insulating film 184 may include, but is not limited to, a tetraethylorthosilicate (TEOS) film, a high density plasma (HDP) oxide film, a boro-phospho-silicate glass (BPSG) film, a flowable chemical vapor deposition (FCVD) oxide film, a SiON film, a SiN film, a SiOC film, a SiCOH film, or any combination thereof.

Next, a via contact VA penetrating the upper insulating structure 180 may be formed. The via contacts VA may each penetrate the upper insulating structure 180 and contact the active contact CA. The source/drain regions 130 may be configured to be electrically connected to the via contact VA through the first metal silicide film 172 and the active contact CA, respectively. A bottom surface of each via contact VA may contact an upper surface of the active contact CA. The via contact VA may include, but is not limited to, W, Mo, and/or ruthenium (Ru).

Next, an upper insulating film 192 may be formed on the upper insulating structure 180 and the via contact VA, and a wiring line M1 penetrating the upper insulating film 192 may be formed. The wiring line M1 may be connected to the via contact VA located below. In some embodiments, the wiring line M1 may extend in the first horizontal direction (X direction). The wiring line M1 may include, but is not limited to, Mo, Cu, W, Co, Ru, Mn, Ti, Ta, Al, a combination thereof, or an alloy thereof.

While the inventive concept has been particularly shown and described with reference to embodiments thereof, it will be understood that various changes in form and details may be made therein without departing from the spirit and scope of the following claims.

What is claimed is:

1. An etchant composition for etching a silicon nitride film, the etchant composition comprising:
an inorganic acid;
a silicon-based additive;
an ammonium-based compound; and
a nitrogen-based additive,
wherein the nitrogen-based additive is an amide-based compound comprising a substituted or unsubstituted aromatic ring having 5 to 15 carbon atoms, a substituted or unsubstituted non-aromatic ring having 5 to 15 carbon atoms, or a substituted or unsubstituted hydrocarbon chain having 1 to 12 carbon atoms.

2. The etchant composition of claim 1, wherein
the amide-based compound comprises N-alkyl formamides such as N-methylformamide, N-ethylformamide, N-propylformamide, N-butylformamide, N-pentylformamide, N-hexylformamide, N-heptylformamide, N-octylformamide, N-nonylformamide, N,N-dimethylformamide, N,N-diethylformamide; N-alkyl acetamides such as N-methylacetamide and N,N-dimethylacetamide; propanamide, butanamide, pentanamide, hexanamide, heptanamide, octanamide, nonanamide, nicotinamide, urea, N-allylthiourea, 2-pyrrolidone, or any combination thereof.

3. The etchant composition of claim 1, wherein the nitrogen-based additive is included in an amount of about 0.1 wt % to about 10 wt % based on the total amount of the etchant composition for etching the silicon nitride film.

4. The etchant composition of claim 1, wherein
the silicon-based additive comprises a silicon-based compound represented by the following Chemical Formula 1, 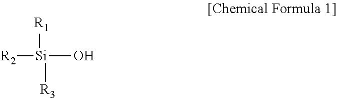
wherein R₁, R₂, and R₃ are each independently selected from the group consisting of a substituted or unsubstituted amino alkyl group having 1 to 20 carbon atoms, a substituted or unsubstituted alkoxy group having 1 to 20 carbon atoms, a substituted or unsubstituted acetyloxy group having 1 to 20 carbon atoms, and a substituted or unsubstituted haloalkylacetyloxy group having 1 to 20 carbon atoms, wherein at least one of R₁, R₂, and R₃ is a substituted or unsubstituted amino alkyl group having 1 to 20 carbon atoms.

5. The etchant composition of claim 1, wherein
the silicon-based additive comprises 3-Aminopropylsilanetriol (APST), methylsilanetriol, chloromethyl (trihydroxy) silane, Methyltriethoxysilane, Methyltrimethoxysilane, tri-(ethyl, methylamino-silane) methyl siloxane, tri-(di-ethylamino-silane) amino propyl siloxane, or any combination thereof.

6. The etchant composition of claim 1, wherein the silicon-based additive is included in an amount of about 0.1 wt % to about 10 wt % based on the total amount of the etchant composition for etching the silicon nitride film.

7. The etchant composition of claim 1, wherein
the ammonium-based compound comprises ammonium chloride, ammonium phosphate, ammonium acetate, ammonium sulfate, ammonium formate, metal amine complex salts, or any combination thereof.

8. The etchant composition of claim 1, wherein the ammonium-based compound is included in an amount of about 0.1 wt % to about 10 wt %.

9. The etchant composition of claim 1, wherein the inorganic acid comprises sulfuric acid, nitric acid, phosphoric acid, silicic acid, hydrofluoric acid, boric acid, hydrochloric acid, perchloric acid or any combination thereof.

10. The etchant composition of claim 1, wherein an etching selectivity of the silicon nitride film with respect to the oxide film of the etchant composition for etching the silicon nitride film is 10 or more.

11. A method of manufacturing a semiconductor device, the method comprising:
forming a stacked structure in which a plurality of sacrificial semiconductor layers and a plurality of nanosheet semiconductor layers are alternately stacked one by one on a substrate;
forming a plurality of dummy gate structures on the stacked structure;
sequentially forming a plurality of insulating spacers and a spacer sacrificial film covering both sidewalls of each of the plurality of dummy gate structures;
forming a first recess penetrating the plurality of sacrificial semiconductor layers and the plurality of nanosheet semiconductor layers by using the plurality of dummy gate structures;
forming a source/drain region inside the first recess; and
removing the spacer sacrificial film using an etchant composition for etching a silicon nitride film,
wherein the etchant composition for etching the silicon nitride film comprises:
an inorganic acid;
a silicon-based additive;
an ammonium-based compound; and
a nitrogen-based additive,
wherein the nitrogen-based additive comprises an amide-based compound comprising a substituted or unsubstituted aromatic ring having 5 to 15 carbon atoms, or a substituted or unsubstituted non-aromatic ring having 5 to 15 carbon atoms, or a substituted or unsubstituted hydrocarbon chain having 1 to 12 carbon atoms.

12. The method of claim 11, wherein
the amide-based compound comprises N-alkyl formamides such as N-methylformamide, N-ethylformamide, N-propylformamide, N-butylformamide, N-pentylformamide, N-hexylformamide, N-heptylformamide, N-octylformamide, N-nonylformamide, N,N-dimethylformamide, N,N-diethylformamide; N-alkyl acetamides such as N-methylacetamide and N,N-dimethylacetamide; propanamide, butanamide, pentanamide, hexanamide, heptanamide, octanamide, nonanamide, nicotinamide, urea, N-allylthiourea, 2-pyrrolidone, or any combination thereof.

13. The method of claim 11, wherein the spacer sacrificial film comprises a silicon nitride film, the insulating spacer includes a silicon oxide film, and the source/drain region includes SiGe or Si doped with an impurity.

14. The method of claim 11, wherein
the silicon-based additive comprises a silicon-based compound represented by the following Chemical Formula 1, 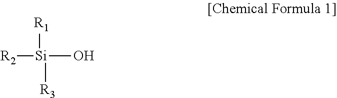
wherein R₁, R₂, and R₃ are each independently selected from the group consisting of a substituted or unsubstituted amino alkyl group having 1 to 20 carbon atoms, a substituted or unsubstituted alkoxy group having 1 to 20 carbon atoms, a substituted or unsubstituted acetyloxy group having 1 to 20 carbon atoms, and a substituted or unsubstituted haloalkylacetyloxy group having 1 to 20 carbon atoms, wherein at least one of R₁, R₂, and R₃ is a substituted or unsubstituted amino alkyl group having 1 to 20 carbon atoms.

15. The method of claim 11, wherein
the silicon-based additive comprises 3-Aminopropylsilanetriol (APST), methylsilanetriol, chloromethyl (trihydroxy) silane, Methyltriethoxysilane, Methyltrimethoxysilane, tri-(ethyl, methylamino-silane) methyl siloxane, tri-(di-ethylamino-silane) amino propyl siloxane, or any combination thereof.

16. The method of claim 13, wherein an etching selectivity of the silicon nitride film with respect to the silicon oxide film of the etchant composition for etching the silicon nitride film is 10 or more.

17. The method of claim 11, wherein
the ammonium-based compound comprises ammonium chloride, ammonium phosphate, ammonium acetate, ammonium sulfate, ammonium formate, metal amine complex salts, or any combination thereof.

18. The method of claim 11, wherein
the nitrogen-based additive is included in an amount of about 0.1 wt % to about 10 wt % based on the total amount of the etchant composition for etching the silicon nitride film, and the silicon-based additive is included in an amount of about 0.1 wt % to about 10 wt % based on the total amount of the etchant composition for etching the silicon nitride film.

19. An etchant composition for etching a silicon nitride film, the etchant composition comprising:
an inorganic acid included in a content of about 7 wt % to about 85 wt % based on the total amount of the etchant composition;
a silicon-based additive included in a content of about 0.1 wt % to about 10 wt % based on the total amount of the etchant composition;
an ammonium-based compound included in a content of about 0.1 wt % to about 10 wt % based on the total amount of the etchant composition;
a nitrogen-based additive included in a content of about 0.1 wt % to about 10 wt % based on the total amount of the etchant composition; and
a solvent,
wherein the nitrogen-based additive comprises an amide-based compound comprising a substituted or unsubstituted aromatic ring having 5 to 15 carbon atoms, a substituted or unsubstituted non-aromatic ring having 5 to 15 carbon atoms, or a substituted or unsubstituted hydrocarbon chain having 1 to 12 carbon atoms.

20. The etchant composition of claim 19, wherein
the amide compound comprises N-alkyl formamides such as N-methylformamide, N-ethylformamide, N-propylformamide, N-butylformamide, N-pentylformamide, N-hexylformamide, N-heptylformamide, N-octylformamide, N-nonylformamide, N,N-dimethylformamide, N,N-diethylformamide; N-alkyl acetamides such as N-methylacetamide and N,N-dimethylacetamide; propanamide, butanamide, pentanamide, hexanamide, heptanamide, octanamide, nonanamide, nicotinamide, urea, N-allylthiourea, 2-pyrrolidone, or any combination thereof.
